(19) United States
(12) Patent Application Publication
(10) Pub. No.: US 2024/0412948 A1
(43) Pub. Date: Dec. 12, 2024

(54) METHODS AND APPARATUS FOR RPS-RF PLASMA CLEAN AND ACTIVATION FOR ADVANCED SEMICONDUCTOR PACKAGING

(71) Applicant: Applied Materials, Inc., Santa Clara, CA (US)

(72) Inventors: Shuran SHENG, Saratoga, CA (US); Ruiping WANG, San Jose, CA (US); Raymond Hoiman HUNG, Palo Alto, CA (US); Ying W. WANG, Singapore (SG); Ke ZHENG, Singapore (SG)

(21) Appl. No.: 18/330,687

(22) Filed: Jun. 7, 2023

(51) Int. Cl. H01J 37/32

(52) U.S. Cl. CPC H01J 37/32357; H01J 37/32403; H01J 37/3244; H01J 2237/20235; H01J 2237/335

(57) ABSTRACT

Embodiments of the disclosure provided herein include a system and method for plasma cleaning and activation using hybrid bonding. The system includes a processing chamber, a substrate support configured to support a substrate during hybrid bonding substrate processing, a gas delivery system coupled to the processing chamber having at least one radical generator, and a controller configured to cause the substrate processing system to form a first layer on a first substrate, dissociate a gas in the at least one radical generator to form a plasma, flow the plasma into the processing volume of the processing chamber for a period of time, exhaust the plasma, by products, and effluent gas from the processing volume after the period of time, and adhere a second layer disposed on a second substrate onto the first layer using a hybrid bonding technique.

### BACKGROUND

### Field

Embodiments of the present disclosure generally relate to semiconductor manufacturing. More particularly, the present disclosure relates to plasma cleaning and activation for advanced semiconductor packaging.

### Description of the Related Art

Copper-dielectric hybrid bonding is a technique that has gained popularity in the semiconductor manufacturing industry due to its ability to integrate two-dimensional materials into semiconductor manufacturing lines. Copper-dielectric hybrid bonding enables a three-dimensional integration by using face to face two-dimensional wafers or dies bonding through back end of line (BEOL) layers to form three-dimensional stacks. The technique involves direct bonding of patterned metal/dielectric surfaces, where copper is one of the metals used for bonding. Copper is a preferred material for bonding due to its superior electrical, thermal, and mechanical properties. Hybrid bonding is used to create reliable connections between the upper and lower pads, and the expansion of copper during the bonding process is crucial to eliminate radial-shaped hollows, which can affect the bonding process.

However, copper dielectric hybrid bonding faces several challenges, including the removal of particles and organic residues from the deposition process on the surface of the metal and dielectric layers while still maintaining control over topography and defectivity.

In addition to these challenges, the copper pads contain particles or organic residues from chemical mechanical polishing (CMP), which may create voids. Voids may be induced by gaseous phase outgassing of surface contaminants and residues. Additionally, voids may be caused by physical particulates or particles interfering directly with bonding between layers.

Accordingly, there is a need for improved hybrid bonding techniques to reduce defectivity and further control topography for use in semiconductor manufacturing.

### SUMMARY

Embodiments described herein generally relate to systems and methods used for semiconductor manufacturing. More particularly, embodiments herein provide for processes and methods for plasma cleaning and activation in advanced semiconductor packaging using hybrid bonding to allow improved bonding characteristics.

In an embodiment, a substrate processing system is provided. The system includes a processing chamber enclosing a processing volume, a substrate support disposed within the processing volume configured to support a substrate during hybrid bonding substrate processing, a gas delivery system fluidly coupled to the processing chamber having at least one radical generator, an exhaust fluidly coupled to the processing volume, and a controller configured to cause the substrate processing system to form a first layer on a first substrate, dissociate a gas in the at least one radical generator to form a plasma, flow the plasma into the processing volume of the processing chamber for a period of time, exhaust the plasma, by products, and effluent gas from the processing volume after the period of time, and adhere a second layer disposed on a second substrate onto the first layer using a hybrid bonding technique.

In another embodiment, a substrate processing system is provided. The system includes a processing chamber enclosing a processing volume, a substrate support disposed within the processing volume configured to support a substrate during hybrid bonding substrate processing, a radio frequency generator coupled to the substrate support, a gas delivery system fluidly coupled to the processing chamber having at least one radical generator, an exhaust fluidly coupled to the processing volume, and a controller configured to cause the substrate processing system to form a first layer on a first substrate, dissociate a gas in the at least one radical generator to form a plasma, flow the plasma into the processing volume for a first period of time, exhaust the plasma, the byproducts, and effluent gas from the processing volume after the first period of time, flow a second gas into the processing volume, bias the substrate support using the radio frequency generator to create a second plasma for a second period of time, exhaust the second plasma, the byproducts, and effluent gas from the processing volume after the second cleaning period, and adhere a second layer disposed on a second substrate onto the first layer using a hybrid bonding technique.

In yet another embodiment, a substrate processing system is provided. The system includes a processing chamber enclosing a processing volume, a substrate support disposed within the processing volume configured to support a substrate during hybrid bonding substrate processing, a first radio frequency generator coupled to the substrate support, a second radio frequency generator coupled to an upper electrode, a gas delivery system fluidly coupled to the processing chamber, an exhaust fluidly coupled to the processing volume, and a controller configured to cause the substrate processing system to form a first layer on a first substrate, flow a gas into the processing volume, bias the substrate support using the first radio frequency generator and the second radio frequency generator to create a plasma for a period of time, exhaust the plasma, byproducts, and effluent gas from the processing volume after the period of time, and adhere a second layer disposed on a second substrate onto the first layer using a hybrid bonding technique.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 illustrates a schematic cross-sectional side view of a processing system, according to certain embodiments.

FIG. 2 illustrates a schematic cross-sectional side view of a processing system, according to certain embodiments.

FIG. 3 illustrates a method for cleaning a chamber or substrate for hybrid bonding, according to certain embodiments.

FIG. 4 illustrates a schematic cross-sectional view of a substrate undergoing the method of FIG. 3, according to certain embodiments.

FIG. 5 illustrates a method for cleaning a chamber or substrate for hybrid bonding, according to certain embodiments.

FIG. 6 illustrates a schematic cross-sectional view of a substrate undergoing the method of FIG. 5, according to certain embodiments.

FIG. 7 illustrates a method for cleaning a chamber or substrate for hybrid bonding, according to certain embodiments.

FIG. 8 illustrates a schematic cross-sectional view of a substrate undergoing the method of FIG. 7, according to certain embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure is generally directed to semiconductor manufacturing. More particularly, the present disclosure relates to plasma clean and activation for hybrid bonding in advanced semiconductor packaging.

The process of preparing substrates is crucial for establishing a strong bond between them using copper-dielectric hybrid bonding (CDHB). Typically, the substrates undergo thorough cleaning using solvents like acetone or isopropyl alcohol, and they may also be treated with plasma to remove any remaining contaminants or activate bonding surfaces. This preparation ensures a clean or activated surface for subsequent steps.

In the next stage, a dielectric layer is deposited onto each substrate, isolating copper layers disposed on the substrates and preventing electrical short circuits. This deposition is carried out using methods such as chemical vapor deposition (CVD) or sputtering. The dielectric layer acts as an insulating barrier between the copper layers, ensuring proper functionality.

An important step in the CDHB process is substrate bonding. Here, the substrates are aligned and fused together through fusion bonding. The copper and silicon-based dielectric hybrid bonding mechanisms for the silicon-based dielectric mating layers includes an initial low-temperature Van der Waals hydrogen bonding followed by annealing to form stronger covalent bonds in between the activated dielectric layer surfaces. Copper pad bonding is achieved by copper diffusion bonding mechanism where the copper surfaces are recessed by CMP dishing to allow the dielectric surfaces to contact and bond first. An additional annealing step then allows copper pad thermal expansion to connect the two copper surfaces through thermal diffusion and plastic deformation for stable bonding.

CDHB, however, presents a significant challenge in advanced semiconductor packaging. Successful implementation requires the use of defect-free, high-yield, and high-throughput integration solutions, as well as advanced semiconductor packaging equipment. Chip-to-Wafer (C2W) bonding large-scale integrated systems are equipped with major modules for wet cleaning, degassing, plasma activation, and precision bonding steps.

However, to meet the key requirements for advanced semiconductor packaging high volume manufacturing (HVM), such as high bonding yields and continuing mean time between failure (MTBF) or mean wafers between cleans (MWBC) gain, and cost of ownership (CoO) reduction, there is a need for more stringent controls on the HB tools. This includes controlling particle or organic defects, bonding surface cleaning or activation process stability, and ensuring chamber hardware long lifetime.

The present disclosure provides systems and methods for remote plasma source and RF plasma chamber and substrate cleans configured for hybrid bonding. The present disclosure provides a processing chamber in a processing system that includes at least one remote plasma source (RPS) disposed at the top of the chamber, on one of the sidewalls of the chamber, or a combination thereof. The processing chamber is also configured for an RF capacitively coupled plasma (CCP) clean which includes a first RF generator coupled to a substrate support disposed within the processing chamber and a second RF generator coupled at the top of the processing chamber, such as to the chamber lid assembly or to a showerhead. A substrate, in preparation for hybrid bonding, may be exposed to an RPS cleaning process, an RF CCP cleaning process, or a combination thereof.

As such, the present disclosure provides improved methods and apparatus for RPS-RF radical and plasma clean and activation and may enable production-worthy HB chamber hardware and bonding surface processes. The present disclosure provides processing tunability and flexibility, long-term reliability, and lowered cost which can be effectively integrated into various semiconductor HVM equipment tools.

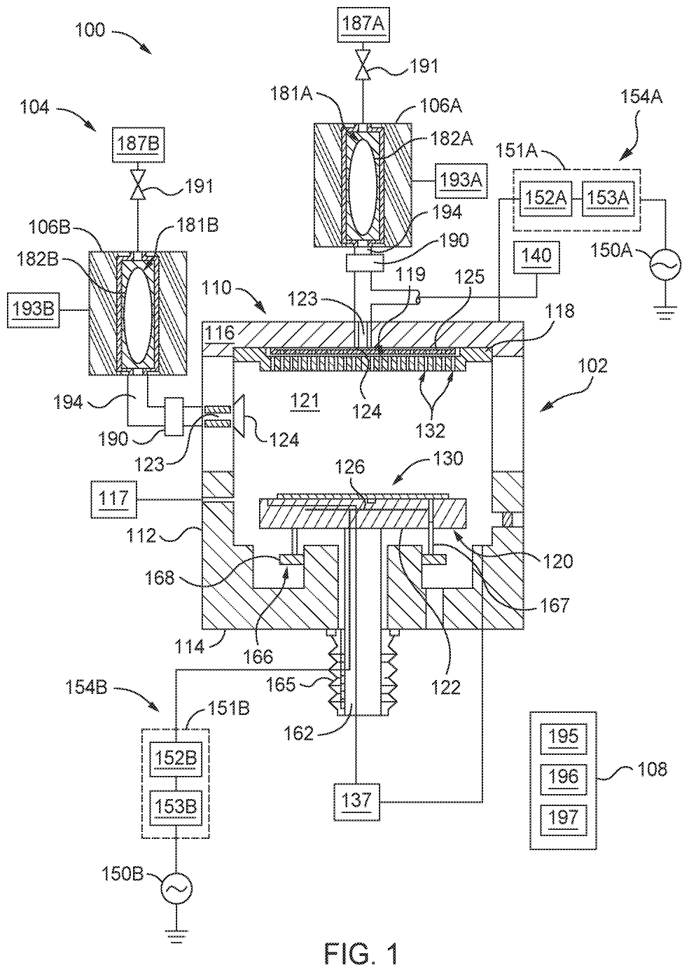

FIG. 1 illustrates a processing system 100 that may be used to perform copper-dielectric hybrid bonding substrate processing methods. The processing system 100 includes a processing chamber 102, a gas delivery system 104 fluidly coupled to the processing chamber 102, and a system controller 108. The processing chamber 102 includes a chamber lid assembly 110, one or more sidewalls 112, and a chamber base 114, which collectively define a processing volume 121. The processing volume 121 is fluidly coupled to an exhaust 117, such as one or more vacuum pumps, used to maintain the processing volume 121 at sub-atmospheric conditions and to evacuate processing gases and processing by-products therefrom.

The chamber lid assembly 110 includes a lid plate 116 and a showerhead 118 coupled to the lid plate 116 to define a gas distribution volume 119. The showerhead 118 faces a substrate support assembly 120 disposed in the processing volume 121. The substrate support assembly 120 is configured to move a substrate support 122 between a raised substrate processing position (as shown) and a lowered substrate transfer position (not shown).

The gas delivery system 104 is fluidly coupled to the processing chamber 102 through at least one gas inlet 123 that is disposed through the lid plate 116, one or more sidewalls 112, or both (both shown). Processing or cleaning gases delivered by the gas delivery system 104 may flow through the at least one gas inlet 123 in the lid plate 116 and a baffle 124 into the gas distribution volume 119 and are distributed into the processing volume 121 through a plurality of openings 132 in the showerhead 118. The chamber lid assembly 110 further includes a perforated diffusion plate 125 disposed between the at least one gas inlet 123 in the lid plate 116 and the showerhead 118. The gases flowed into the gas distribution volume 119 are first diffused by the diffusion plate 125 to provide a more uniform or desired distribution of gas flow into the processing volume 121. Cleaning gases can also be delivered through the gas inlet 123 in the one or more sidewalls 112 and into the processing volume 121. Processing gases and processing by-products are evacuated from the processing volume 121 through openings in the one or more sidewalls 112.

A purge gas source 137 in fluid communication with the processing volume 121 is used to flow a chemically inert purge gas, such as argon (Ar) and helium (He), into a region disposed beneath the substrate support 122, e.g., through the opening in the chamber base 114 surrounding a moveable support shaft 162 supporting the substrate support 122. The purge gas may be used to create a region of positive pressure below the substrate support 122 when compared to the pressure in the processing volume 121 during substrate processing. Typically, purge gas introduced through the chamber base 114 flows up and around the edges of the substrate support 122 to be evacuated from the processing volume 121 through openings in the one or more sidewalls 112.

The substrate support assembly 120 includes the movable support shaft 162 that may be surrounded by a bellows 165. The substrate support assembly 120 includes a lift pin assembly 166 comprising a plurality of lift pins 167 coupled to a lift pin hoop 168. The plurality of lift pins 167 are movably disposed in openings formed through the substrate support 122. When the substrate support 122 is disposed in a lowered substrate transfer position (not shown), the plurality of lift pins 167 extend above a substrate receiving surface of the substrate support 122 to lift a substrate 130 and provide access to a backside surface of the substrate 130. When the substrate support 122 is in a raised or processing position, the plurality of lift pins 167 recede beneath the substrate receiving surface of the substrate support 122 to allow the substrate 130 to rest thereon. The plurality of lift pins 167 may lift the substrate 130 during processing, such as during a remote plasma source cleaning process or an RF capacitively coupled cleaning process, such that cleaning gases and cleaning plasma may flow on opposing sides of the substrate 130, e.g., the front side and the backside of the substrate 130.

As shown, the processing system 100 may be configured to form a capacitively coupled plasma (CCP), including an upper electrode (e.g., lid plate 116) disposed adjacent the processing volume 121 facing a lower electrode (e.g., substrate support assembly 120) disposed in the processing volume 121 opposite the upper electrode. A first plasma generator assembly 154A includes a first RF generator 150A and a first RF generator assembly 151A, and is electrically coupled to the upper electrode to deliver an RF signal configured to ignite and maintain a plasma. The first RF generator 150A includes a first RF matching circuit 153A and a first filter assembly 152A disposed within the first RF generator assembly 151A. The lower electrode (e.g., the substrate support assembly 120) is coupled to a second plasma generator assembly 154B. As shown in FIG. 1, one or more components of the substrate support assembly 120, such as a substrate electrode 126 embedded in the substrate support assembly 120, is electrically coupled to the second plasma generator assembly 154B. The second RF generator 150B includes a second RF matching circuit 153B and a second filter assembly 152B disposed within the second RF generator assembly 151B.

Alternatively, the showerhead 118 may be electrically coupled to the first RF generator 150A to ignite and maintain a plasma of processing gases flowed into the processing volume 121 through capacitive coupling therewith. In some embodiments, the processing chamber 102 comprises an inductive plasma generator (not shown), and a plasma is formed through inductively coupling an RF power to the processing gas.

The second plasma generator assembly 154B, which includes a second RF generator 150B and a second RF generator assembly 151B, is generally configured to deliver a desired amount of a continuous wave (CW) or pulsed RF power at a desired substantially fixed sinusoidal waveform frequency to the substrate electrode 126 of the substrate support assembly 120 based on control signals provided from the system controller 108. During processing, the second plasma generator assembly 154B is configured to deliver RF power (e.g., an RF signal) to the substrate electrode 126 disposed proximate to the substrate support 122, and within the substrate support assembly 120. The RF power delivered to the substrate electrode 126 is configured to ignite and maintain the processing plasma using the processing gases disposed in the processing volume 121 and fields generated by the RF power (RF signal) delivered to the substrate electrode 126 by the second RF generator 150B.

The gas delivery system 104 may include one or more remote plasma sources, e.g., a first radical generator 106A and a second radical generator 106B, a deposition gas source 140, and a conduit system 194 fluidly coupling the first radical generator 106A and second radical generator 106B and the deposition gas source 140 to the processing volume 121. The first radical generator 106A may be disposed on a top of the processing chamber 102 and the second radical generator 106B may be disposed on a sidewall of the processing chamber 102. Alternatively, the second radical generator 106B may be disposed on the top of the processing chamber 102 and the first radical generator 106A may be disposed on the sidewall of the processing chamber 102. The first and second radical generators 106A, 106B are fluidly coupled to the processing volume 121 through gas inlets 123. A distal end of each gas inlet 123 includes a baffle 124 to produce a laminar flow of gas or plasma entering the processing volume 121 from the first and second radical generators 106A, 106B. The gas delivery system 104 further includes a plurality of isolation valves 190, respectively disposed between the first radical generator 106A and the lid plate 116 and between the second radical generator 106B and gas inlet 123, which may be used to fluidly isolate each of first radical generator 106A and the second radical generator 106B from the processing chamber 102.

Although two remote plasma sources are depicted in FIG. 1, the present disclosure contemplates the use of only one remote plasma source, e.g., the first radical generator 106A. In this single-RPS configuration, the first radical generator 106A may be disposed on top of or on any of the sidewalls 112 of the processing chamber 102.

The first radical generator 106A includes a first plasma chamber volume 181A, and the second radical generator 106B includes a second plasma chamber volume 181B. The first radical generator 106A is coupled to a first power supply 193A, and the second radical generator 106B is coupled to a second power supply 193B. The first power supply 193A is used to ignite and maintain a plasma of gases delivered to the first plasma chamber volume 181A from a first gas source 187A. The second power supply 193B is used to ignite and maintain a plasma of gases delivered to the second plasma chamber volume 181B from a second gas source 187B. Either the first radical generator 106A or the second radical generator 106B may be used to generate cleaning radicals used in a chamber clean process by igniting and maintaining a cleaning plasma from a cleaning gas mixture delivered from the first gas source 187A or the second gas source 187B, respectively. The cleaning gas mixture may include H₂, N₂, Ar, He, NH₃, NF₃, clean dry air (CDA), or a combination thereof.

Suitable remote plasma sources which may be used for one or both of the first radical generator 106A and the second radical generator 106B include radio frequency (RF) or very high radio frequency (VHRF) capacitively coupled plasma (CCP) sources, inductively coupled plasma (ICP) sources, microwave-induced (MW) plasma sources, electron cyclotron resonance (ECR) plasma sources, helicon plasma sources, or other high-density plasma (HDP) sources.

Operation of the processing system 100 is facilitated by the system controller 108. The system controller 108 includes a programmable central processing unit (CPU) 195, which is operable with a memory 196 (e.g., non-volatile memory) and support circuits 197. The CPU 195 is one of any form of general-purpose computer processor used in an industrial setting, such as a programmable logic controller (PLC), for controlling various chamber components and sub-processors. The memory 196, coupled to the CPU 195, facilitates the operation of the processing chamber. The support circuits 197 are conventionally coupled to the CPU 195 and comprise cache, clock circuits, input/output subsystems, power supplies, and the like, and combinations thereof coupled to the various components of the processing system 100 to facilitate control of substrate processing operations therewith.

The instructions in memory 196 are in the form of a program product, such as a program that implements the methods of the present disclosure. In one example, the disclosure may be implemented as a program product stored on computer-readable storage media for use with a computer system. The programs of the program product define functions of the embodiments including the methods described herein. Thus, the computer-readable storage media, when carrying computer-readable instructions that direct the functions of the methods described herein, are embodiments of the present disclosure.

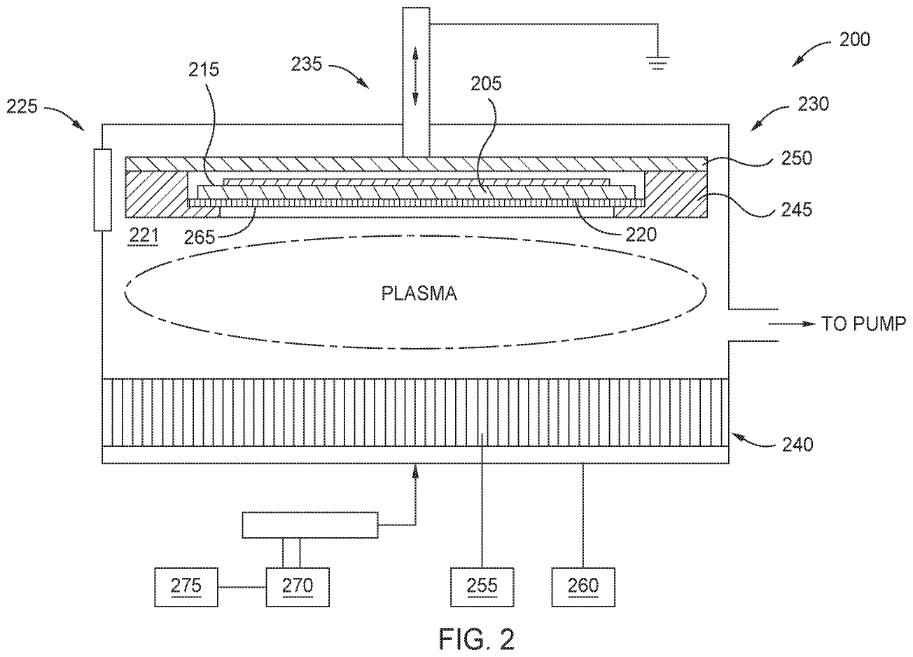

FIG. 2 illustrates a schematic cross-sectional side view of a processing chamber 200. The processing chamber 200 illustrates an alternative processing chamber configured for backside processing. The backside processing chamber 200 is a plasma enhanced chemical vapor deposition chamber. In some embodiments, the backside processing chamber 200 shown in FIG. 2 is also capable of an etch process using plasma. In other embodiments, the backside processing chamber 200 is either capable of deposition or etching such that separate chambers are necessary for each process.

The backside processing chamber 200 is configured to receive a substrate 205 and clean or activate a backside surface 220 of the substrate 205. The substrate 205 is transferred into the backside processing chamber 200 via a transfer port 225 and to a stage 230. The stage 230 is adapted to receive and hold the substrate 205 in a face down orientation (i.e., with the front-side surface 215 facing upward and the backside surface 220 facing downward). The stage 230 is coupled to a stem 235 that is movable in at least a vertical (up and down) direction to change a spacing between the substrate 205 and a perforated faceplate 240. The stage 230 includes a holder 245 that suspends the substrate 205 from an edge thereof. The stage 230 includes a heater 250 to control the temperature of the substrate 205.

The backside processing chamber 200 is configured to deposit films onto the backside surface 220 or etch films previously formed on the backside surface 220. The backside processing chamber 200 is coupled to a power source 255 for forming a plasma in the chamber. The power source 255 is configured to form a plasma by applying a radio frequency (RF) power, a very high radio frequency (VHF) power in a capacitively coupled plasma application, an inductively coupled power (ICP) application, a microwave power application, a reactive ion etching (RIE) power application, or an electron cyclotron resonance (ECR) power application. The backside processing chamber 200 is also coupled to a gas source 260.

In a deposition process, the gas source 260 includes precursor gases for forming dielectric films, semiconductive films, or metal films using the plasma as the backside coating. In the deposition process, a mask 265 may optionally be utilized to form a specific pattern of films on the backside surface 220 of the substrate 205. In an etch process, the gas source 260 includes various gases utilized to form the plasma for removing dielectric films, semiconductive films, or metal films previously formed on the backside surface 220 of the substrate 205.

The backside processing chamber 200 is also coupled to a remote plasma chamber 270. The remote plasma chamber 270 is coupled to a cleaning gas source 275. Cleaning gases from the cleaning gas source 275 are provided to the remote plasma chamber 270 where the cleaning gases are energized and provided to the backside processing chamber 200 as a plasma that is utilized to clean interior components of the backside processing chamber 200.

The processing chamber 200 is also configured for cleaning using a capacitively coupled plasma. The power source 255 may be adapted to deliver RF energy to a processing region 221 of the processing chamber 200 through one or more parts of the processing chamber 200. During operation of the processing chamber 200, the power source 255 is used to bias the portion of the processing chamber 200 (e.g., the bottom of the processing chamber 200) to form a plasma in the processing region 221.

During processing, the stem 235 may be connected to an RF generator (not shown) to apply an RF bias power to portions of the holder 245 to pull the ions present in a plasma to a surface of the substrate 205. In one embodiment, the holder 245 is grounded, DC biased, or is electrically floating during the plasma process in order to minimize ion bombardment damage of substrate 205.

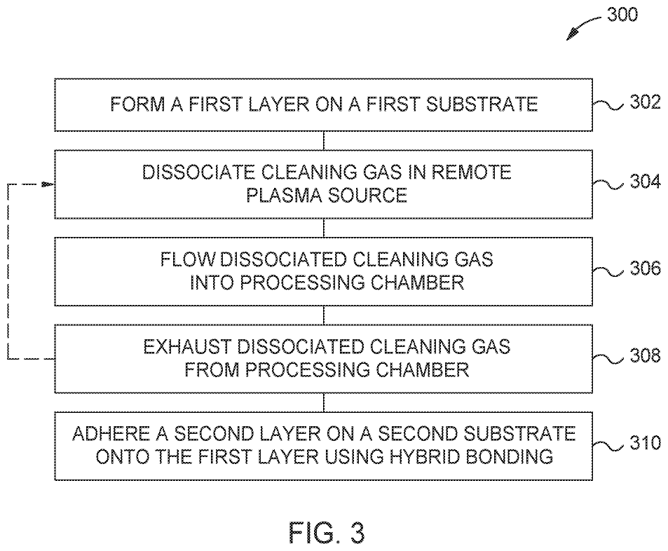

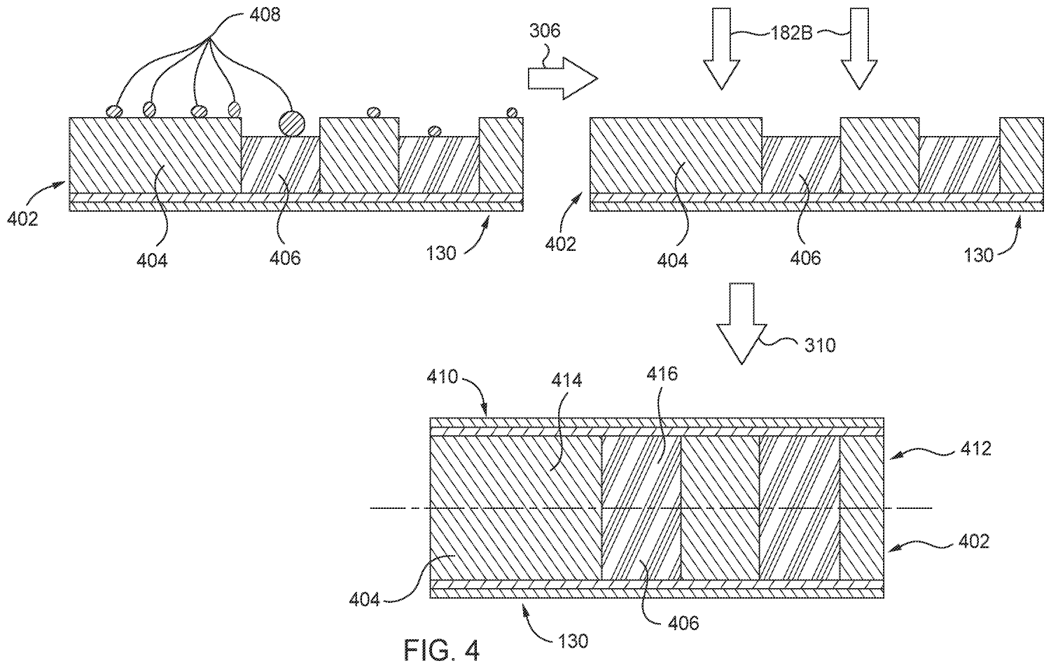

FIG. 3 illustrates a method 300 for a remote plasma source clean for hybrid bonding in advanced packaging of a substrate. The method 300 may be used with the processing system 100 of FIG. 1 or the processing system 200 of FIG. 2 to clean the substrate 130 and the processing volume 121 for hybrid bonding. FIG. 4 illustrates a substrate undergoing the method 300 and is referenced in the description of method 300.

The method 300 begins with forming a first layer 402 on a first substrate (e.g., substrate 130) in block 302. The first layer 402 may comprise a plurality of layers and may include a variety of materials. In particular, the first layer 402 may include at least one dielectric portion 404 and at least one metallic portion 406. The dielectric portion 404 may comprise any suitable dielectric, such as silicon dioxide or silicon nitride. The metallic portion 406 may include any electrically conductive metal, such as copper, aluminum, tungsten, or titanium. After formation of the first layer 402, residues or particles 408 may remain on the surface of the first layer 402. These residues or particles 408 may interfere with hybrid bonding and prevent proper adhesions between stacks.

To remove the residues or particles 408 and prepare the surface of the first layer 402 for bonding, the surface of the first layer 402 is cleaned and/or activated. In block 304, a cleaning or activating gas is dissociated and reactive radicals are generated in a remote plasma source, such as the first radical generator 106A to clean and/or activate the first layer 402. The cleaning or activating gas may include any of the cleaning gas mixtures discussed with respect to FIG. 1. As described in reference to FIG. 1, the cleaning or activating gas is ignited to form a cleaning/activation plasma 182A within the first plasma chamber volume 181A. The cleaning/activation plasma 182A is then flowed into the processing volume 121 of the processing chamber 102 in block 306 during a cleaning/activation period. The cleaning period may be of any suitable length, such as 10 seconds to about 30 minutes, such as about 30 seconds to about 5 minutes, such as about 1 minute. The first layer 402 is exposed to the cleaning/activation plasma 182A causing the residues or particles 408 on the surface of the first layer 402 to react and vaporize to produce an effluent gas.

The cleaning/activation plasma 182A, exhaust products, and the effluent gas are exhausted from the processing volume 121 at the completion of the cleaning/activation process (e.g., after the cleaning/activation period) in block 308. The method 300 may return to block 304 for another iteration of the RPS cleaning/activation process, if desired, for as many iterations as required. The first layer 402 of a first substrate may then undergo hybrid bonding with a complementary layer 412 disposed on a complementary substrate 410 in block 310. The complementary layer 412 may include at least one complementary dielectric portion 414 and at least one complementary metallic portion 416. The complementary layer 412 may also have been cleaned and/or activated using a remote plasma source as described in blocks 304 through 308 prior to the hybrid bonding operation in block 310.

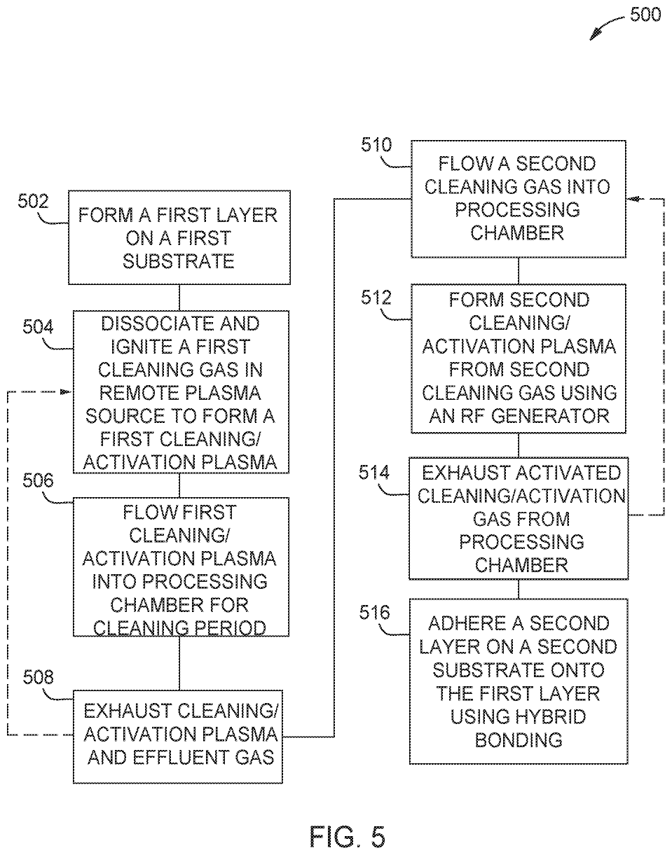

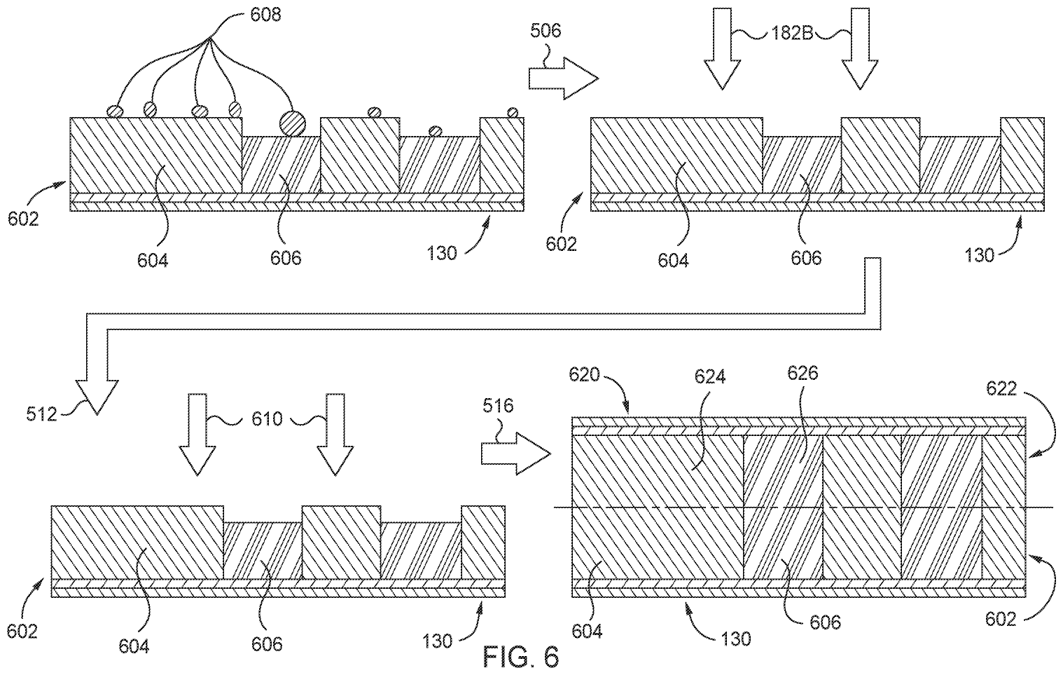

FIG. 5 illustrates a method 500 for a remote plasma source (RPS) and radio frequency (RF) capacitively coupled plasma (CCP) joint cleaning/activation process for hybrid bonding in advanced packaging of a substrate. The method 500 may be used with the processing system 100 of FIG. 1 or the processing system 200 of FIG. 2 to clean and/or activate the substrate 130 and the processing volume 121 for hybrid bonding. FIG. 6 illustrates a substrate undergoing the method 500 and is referenced in the description of method 500.

The method 500 begins with forming a first layer 602 on a first substrate (e.g., substrate 130) in block 502. The first layer 602 may comprise a plurality of layers and may include a variety of materials. In particular, the first layer 602 may include at least one dielectric portion 604 and at least one metallic portion 606. The dielectric portion 604 may comprise any suitable dielectric, such as silicon dioxide or silicon nitride. The metallic portion 606 may include any electrically conductive metal, such as copper, aluminum, tungsten, or titanium. After formation of the first layer 602, residues or particles 608 may remain on the surface of first layer 602. These residues or particles 608 may interfere with hybrid bonding and prevent proper adhesions between stacks.

To remove the residues or particles 608 and prepare the surface of the first layer 602 for bonding, the surface of the first layer 602 is cleaned and/or activated. In block 504, a first cleaning or activating gas is dissociated and reactive radicals are generated in a remote plasma source, such as the first radical generator 106A. The first cleaning or activating gas may be any of the cleaning gas mixtures discussed with respect to FIG. 1. As described in reference to FIG. 1, the first cleaning or activating gas is ignited to form a first cleaning/activation plasma 182A within the first plasma chamber volume 181A. The first cleaning/activation plasma 182A is then flowed into the processing volume 121 of the processing chamber 102 in block 506 for a first cleaning period. The first cleaning period may be of any suitable length, such as 10 seconds to about 30 minutes, such as about 30 seconds to about 5 minutes, such as about 1 minute. The first layer 602 is exposed to the cleaning/activation plasma 182A causing the residues or particles 608 on the surface of the first layer 602 to react and vaporize to produce an effluent gas.

The cleaning/activation plasma 182A, the byproducts, and the effluent gas may be exhausted from the processing volume 121 at the completion of the cleaning/activation process in block 508. The method 500 may return to block 504 for another iteration of the RPS cleaning/activation process, if desired, for as many iterations as required.

A second cleaning or activating gas may then be flowed into the processing volume 121 of the processing chamber 102 in block 510. The second cleaning or activating gas may comprise the same composition as the first cleaning or activating gas or may comprise a different composition configured to react to any remaining residues or particles 608, or to activate bonding surfaces.

In block 512, the first layer 602 undergoes a radio frequency (RF) capacitively coupled plasma (CCP) cleaning process where the substrate support assembly 120 is biased using at least one of the first RF generator 150A and the second RF generator 150B. The second cleaning or activating gas is ignited and dissociated within the processing chamber 102 to form a second cleaning/activation plasma 610 where ions from the second cleaning/activation plasma 610 strike the remaining residues or particles 608 on the surface of the first layer 602, producing a second effluent gas. The second cleaning/activation plasma 610 is present in the processing volume 121 for a second cleaning period. The second cleaning period may be of any suitable length, such as 10 seconds to about 30 minutes, such as about 30 seconds to about 5 minutes, such as about 1 minute and may be shorter or longer than the first cleaning period.

The second cleaning/activation plasma 610, the byproducts, and the second effluent gas may be exhausted from the processing volume 121 in block 514. The method 500 may return to block 510 for another iteration of the RF CCP cleaning/activation process, if desired, for as many iterations as required. The first layer 602 may then undergo hybrid bonding in block 516 with a complementary layer 622 disposed on a complementary substrate 620. The complementary layer 622 may include at least one complementary dielectric portion 624 and at least one complementary metallic portion 626. The complementary layer 622 may also have been cleaned and/or activated using a remote plasma source and CCP source as described in blocks 504 through 514.

Alternatively, the RPS cleaning/activation process (e.g., blocks 504-508) and the RF CCP cleaning/activation process (e.g., blocks 510-514) may be interchanged such that the RF CCP cleaning/activation process precedes the RPS cleaning/activation process. Additionally, the RPS cleaning/activation process and the RF CCP cleaning/activation process may be repeated as many times as desired in any order desired. For example, a cleaning/activation process may include a first round of RPS cleaning/activation followed by a first round of RF CCP cleaning/activation then a second round of RPS cleaning/activation. Another example cleaning/activation process may include a first round of RF CCP cleaning/activation, then a second round of RF CCP cleaning/activation, followed by a first round of RPS cleaning/activation.

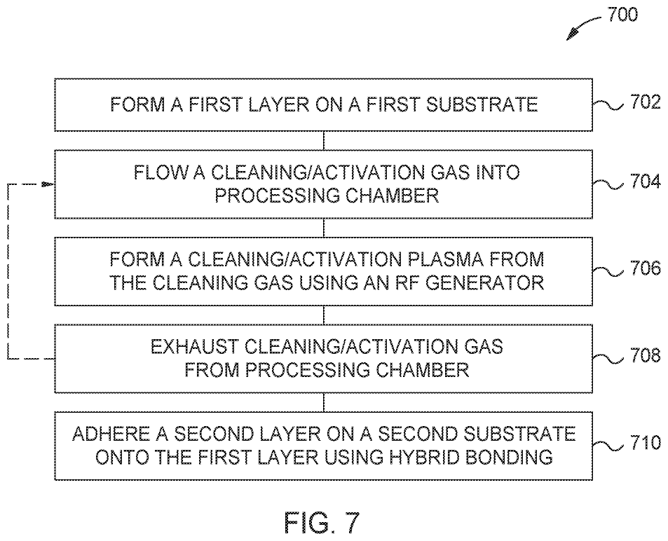

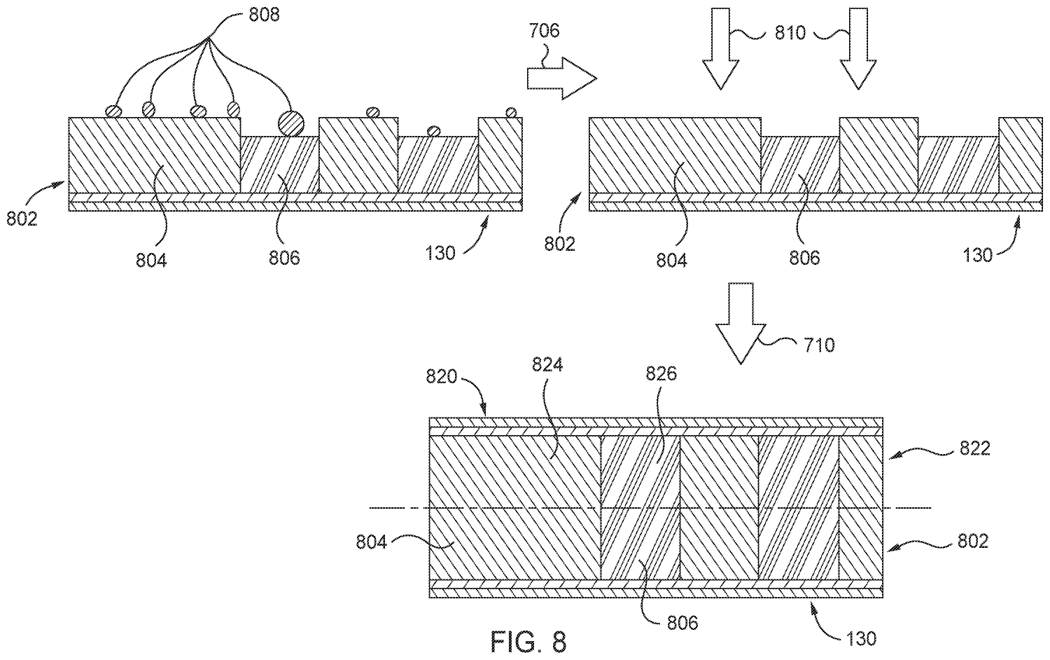

FIG. 7 illustrates a method 700 for a remote plasma source clean or activation for hybrid bonding in advanced packaging of a substrate. The method 700 may be used with the processing system 100 of FIG. 1 to clean and/or activate the substrate 130 and the processing volume 121 for hybrid bonding. FIG. 8 illustrates a substrate undergoing the method 700 and is referenced in the description of method 700.

The method 700 begins with forming a first layer 802 on a first substrate (e.g., substrate 130) in block 702. The first layer 802 may comprise a plurality of layers and may include a variety of materials. In particular, the first layer 802 may include at least one dielectric portion 804 and at least one metallic portion 806. The dielectric portion 804 may comprise any suitable dielectric, such as silicon dioxide or silicon nitride. The metallic portion 806 may include any electrically conductive metal, such as copper, aluminum, tungsten, or titanium. After formation of the first layer 802, residues or particles 808 may remain on the surface of first layer 802. These residues or particles 808 may interfere with hybrid bonding and prevent proper adhesions between stacks.

To remove the residues or particles 808 and prepare the surface of the first layer 802 for bonding, the surface of the first layer 802 is cleaned and/or activated. In block 704, a cleaning or activating gas is flowed into the processing volume 121 of the processing chamber 102. The cleaning or activating gas may include any of the cleaning gas combinations discussed with respect to FIG. 1. The cleaning or activating gas is then ignited and dissociated in the processing volume 121 to form a cleaning/activation plasma 810 when the substrate support assembly 120 and the lid plate 116 are biased using the first RF generator 150A and the second RF generator 150B in block 706. The first layer 802 is exposed to the cleaning/activation plasma 810 causing the residues or particles 808 on the surface of the first layer 802 to react and vaporize to produce an effluent gas.

The cleaning/activation plasma 810, the byproducts, and the effluent gas are exhausted from the processing volume 121 at the completion of the cleaning/activation process in block 708. The method 700 may return to block 704 for another iteration of the RF CCP cleaning/activation process, if desired, for as many iterations as required. The first layer 802 may then undergo hybrid bonding with a complementary layer 822 disposed on a complementary substrate 820 in block 710. The complementary layer 822 may include at least one complementary dielectric portion 824 and at least one complementary metallic portion 826. The complementary layer 822 may also have been cleaned or activated using a CCP cleaning process as described in blocks 704 through 708.

The present disclosure provides the needed flexibility for configuring radical and plasma RPS/RF clean or activation to meet various cleaning or surface preparation or activation requirements such as combined or separate RPS or RF plasma treatments. For example, RPS, RF plasma, RF-assisted RPS, RPS-assisted RF plasma, or intermittent RPS and RF treatments can be selected and performed to remove various residues or particles left on the chamber parts or wafer/die surfaces, and to achieve damage-free hybrid bonding surface activation or cleaning.

When introducing elements of the present disclosure or exemplary aspects or embodiment(s) thereof, the articles “a,” “an,” “the” and “said” are intended to mean that there are one or more of the elements.

The terms “comprising,” “including” and “having” are intended to be inclusive and mean that there may be additional elements other than the listed elements.

The term “coupled” is used herein to refer to the direct or indirect coupling between two objects. For example, if object A physically touches object B and object B touches object C, the objects A and C may still be considered coupled to one another—even if objects A and C do not directly physically touch each other. For instance, a fist object may be coupled to a second object even though the first object is never directly in physical contact with the second object.

While the foregoing is directed to embodiments of the present disclosure, other and further embodiments of the disclosure may be devised without departing from the basic scope thereof, and the scope thereof is determined by the claims that follow.

What is claimed is:

1. A substrate processing system, comprising:
a processing chamber enclosing a processing volume;
a substrate support disposed within the processing volume configured to support a substrate during hybrid bonding substrate processing;
a gas delivery system fluidly coupled to the processing chamber comprising at least one radical generator;
an exhaust fluidly coupled to the processing volume; and
a controller configured to cause the substrate processing system to:
(a) form a first layer on a first substrate;
(b) dissociate a gas in the at least one radical generator to form a plasma;
(c) flow the plasma into the processing volume of the processing chamber for a period of time;
(d) exhaust the plasma, by products, and effluent gas from the processing volume after the period of time; and
(e) adhere a second layer disposed on a second substrate onto the first layer using a hybrid bonding technique.

2. The substrate processing system of claim 1, wherein the first layer comprises dielectric portions and metallic portions, the dielectric portions comprising silicon dioxide and the metallic portions comprising copper.

3. The substrate processing system of claim 1, wherein the gas comprises H₂, N₂, Ar, He, NH₃, NF₃, clean dry air (CDA), or a combination thereof.

4. The substrate processing system of claim 1, wherein the at least one radical generator comprises a first radical generator disposed on a top of the processing chamber or a second radical generator disposed on a sidewall of the processing chamber.

5. The substrate processing system of claim 1, wherein the processing chamber is configured for front-side and back-side processing.

6. The substrate processing system of claim 5, wherein the substrate support comprises lift pins configured to support a substrate such that the plasma flows on opposing sides of the substrate.

7. The substrate processing system of claim 1, wherein the controller is further configured to cause the substrate processing system to repeat (b), (c), and (d) iteratively before performing (e).

8. A substrate processing system, comprising:
a processing chamber enclosing a processing volume;
a substrate support disposed within the processing volume configured to support a substrate during hybrid bonding substrate processing;
a radio frequency generator coupled to the substrate support;
a gas delivery system fluidly coupled to the processing chamber comprising at least one radical generator;
an exhaust fluidly coupled to the processing volume; and
a controller configured to cause the substrate processing system to:
(a) form a first layer on a first substrate;
(b) dissociate a first gas in the at least one radical generator to form a plasma;
(c) flow the plasma into the processing volume for a first period of time;
(d) exhaust the plasma, byproducts, and effluent gas from the processing volume after the first period of time;
(e) flow a second gas into the processing volume;
(f) bias the substrate support using the radio frequency generator to create a second plasma for a second period of time;
(g) exhaust the second plasma, byproducts, and effluent gas from the processing volume after the second cleaning period; and
(h) adhere a second layer disposed on a second substrate onto the first layer using a hybrid bonding technique.

9. The substrate processing system of claim 8, wherein the first layer comprises dielectric portions and metallic portions, the dielectric portions comprising silicon dioxide and the metallic portions comprising copper.

10. The substrate processing system of claim 8, wherein the first gas comprises H₂, N₂, Ar, He, NH₃, NF₃, clean dry air (CDA), or a combination thereof.

11. The substrate processing system of claim 8, wherein the at least one radical generator comprises a first radical generator disposed on a top of the processing chamber or a second radical generator disposed on a sidewall of the processing chamber.

12. The substrate processing system of claim 8, wherein the processing chamber is configured for front-side and back-side processing.

13. The substrate processing system of claim 8, wherein the second gas comprises H₂, N₂, Ar, He, NH₃, NF₃, clean dry air (CDA), or a combination thereof and has a different composition from the first gas.

14. The substrate processing system of claim 8, wherein the controller is further configured to repeat at least one of (b), (d), and (d), or (e), (f), and (g) iteratively before performing (h).

15. A substrate processing system, comprising:
a processing chamber enclosing a processing volume;
a substrate support disposed within the processing volume configured to support a substrate during hybrid bonding substrate processing;
a first radio frequency generator coupled to the substrate support;
a second radio frequency generator coupled to an upper electrode;
a gas delivery system fluidly coupled to the processing chamber;
an exhaust fluidly coupled to the processing volume; and
a controller configured to cause the substrate processing system to:
(a) form a first layer on a first substrate;
(b) flow a gas into the processing volume;
(c) bias the substrate support using the first radio frequency generator and the second radio frequency generator to create a plasma for a period of time;
(d) exhaust the plasma, byproducts, and effluent gas from the processing volume after the period of time; and
(e) adhere a second layer disposed on a second substrate onto the first layer using a hybrid bonding technique.

16. The substrate processing system of claim 15, wherein the first layer comprises dielectric portions and metallic portions, the dielectric portions comprising silicon dioxide and the metallic portions comprising copper.

17. The substrate processing system of claim 15, wherein the gas comprises H₂, N₂, Ar, He, NH₃, NF₃, clean dry air (CDA), or a combination thereof.

18. The substrate processing system of claim 15, wherein the upper electrode is a chamber lid or a showerhead disposed within the processing chamber.

19. The substrate processing system of claim 15, wherein the processing chamber is configured for front-side and backside processing.

20. The substrate processing system of claim 15, wherein the controller is further configured to repeat (b), (c), and (d) iteratively before performing (e).
